(19) United States
(12) Patent Application Publication
(10) Pub. No.: US 2026/0179672 A1
(43) Pub. Date: Jun. 25, 2026

(54) CELL OPERATION CIRCUIT

(71) Applicant: Ferroelectric Memory GmbH, Dresden (DE)

(72) Inventors: Fabio Tassan Caser, Villasanta (IT); Luigi Paone, Pioltello (IT); Johannes Ocker, Dresden (DE)

(21) Appl. No.: 18/990,075

(22) Filed: Dec. 20, 2024

(51) Int. Cl. G11C 11/22

(52) U.S. Cl. CPC G11C 11/2295; G11C 11/221; G11C 11/2255

(57) ABSTRACT

A cell operation circuit for operating a set of memory elements comprises: an access circuitry comprising a first input terminal and a second input terminal and being configured to receive a first operation voltage at the first input terminal and to receive a second operation voltage at second input terminal to access a first memory element of the set; a control circuitry configured to provide a protection voltage, to which a second memory element of the set is exposed, when the first memory element is accessed by the access circuitry, wherein the protection voltage is between the first operation voltage and the second operation voltage.

### TECHNICAL FIELD

This disclosure relates to implementations for the operation of non-volatile memories, and in particular, of memories that include state-programmable memory elements for storing information in a memory cell.

### BACKGROUND

Non-volatile memories allow for storing information in a memory, where the stored information is retained in the memory even after external power to the memory has been removed. Memories are typically formed from a number of memory cells, where each memory cell is able to store information in a state-programmable memory element (e.g., a ferroelectric memory element such as a ferroelectric capacitor) that is capable of retaining the written information based on a programmed state of the state-programmable memory element that is retained even after its power source has been removed. The programmed state usually represents a binary value (e.g., a logic “1” or a logic “0”) that may be read out at later time by applying a read voltage sufficient to switch the state of the state-programmable memory element, and then determining the read state from the switching charge injected when the state-programmable memory element changes states. However, conventional configurations suffer from various deficiencies, leading to potential read errors and reliability issues.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A shows an exemplary memory cell including a state-programmable memory element in a schematic circuit diagram and FIG. 1B shows a graph of an exemplary hysteresis curve of such a state-programmable memory element indicating threshold voltages and logic states;

FIG. 2A to FIG. 2C show each a device in a schematic circuit diagram;

FIG. 3A and FIG. 3B show each a cell operation circuit in a schematic circuit diagram;

FIG. 4A and FIG. 4B show each a device in various schematic views;

FIGS. 5A and 5B show each an operation schema in a schematic timing diagram illustrating various operation phases; and

FIG. 6A a graph of an exemplary hysteresis curve of such a state-programmable memory element indicating threshold voltages and logic states
and 6B show each an exemplary memory cell arrangement in a schematic diagram.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices. However, it may be understood that aspects described in connection with methods may similarly apply to the devices, and vice versa.

In general, the term “bit” (also referred to as digital bit or as binary digit) relates to the fundamental unit of information storage, transmission and processing. The value of a bit represents a logical state selected from only two logical states, which are commonly referred to as “0” or “1”, or as “on” and “off”. In context of information storage, each of these logical states may be represented by a physical state (also referred to as programmed state or memory state) of a state-programmable memory element, e.g., the polarization direction of the memory element.

The term “switch” (also referred to as switch circuitry) relates to a circuitry including two terminals and a connection between the two terminals. The switch is configured to change an impedance (e.g., resistance) of the connection, e.g., in a controlled manner and/or as a function of a signal (e.g., control signal) to which the switch (e.g., a control terminal thereof) is exposed. For example, the impedance (e.g., resistance) of the connection may be decreased, when the voltage of the control signal increases, and increased otherwise. Herein, the switch is implemented by one or more transistors (e.g., a gate terminal being supplied with the control signal), which is understood as not limiting. The references made hereto may apply in analogy to any other implementation of the switch.

In general, a non-volatile memory device is typically formed from a number of memory cells, where each memory cell typically stores one of two (e.g., logical) states: a first state representing the off state (e.g., representing a digital bit of “0”) and a second state representing the on state (e.g., representing a digital bit of “1”). The individual memory cells of the memory are typically organized into control groupings of cells (also referred to as set), where each cell may be individually addressed but have a common operation schema for biasing the cells via control lines such as bitlines (e.g., for operating the cells grouped in the same column), wordlines (e.g., for operating cells grouped in the same row), and/or platelines (e.g., for operating cells grouped so as to share a common node such as a same “plate”). Among other components, a memory cell may include a state-programmable memory element (e.g., a ferroelectric memory element such as a ferroelectric capacitor) that is capable of retaining the written information by writing one of the remanent states of the memory element so that it may be read out at a later time during a read operation.

As used throughout this disclosure, a state of a memory element is described as “remanent” where the memory element is capable of retaining its programmed state even when it is not connected to a power source. As also used throughout, the current remanent state to which the memory element has been set may be referred to as the “stored” state, the “written” state, the “memory” state, or the “programmed” state. As should be understood, when referring to a state-programmable memory element, the terms “write,” “store,” or “program” are used generically to refer to setting the remanent state of the state-programmable memory element(s). As is understood, the term “voltage” (also referred to as electrical potential difference), e.g., with respect to “a bitline voltage”, “a wordline voltage,” “a plateline voltage,” and the like, may refer to an electrical potential, e.g., its value with respect to a lower operation voltage (e.g., ground). The “voltage across” a component may be used herein to denote a voltage drop from a node on one side of a component (e.g. one side of a capacitor) to a node on the other side of the component (e.g., the other side of the capacitor).

When a state-programmable memory element includes ferroelectric material (e.g., a ferroelectric capacitor), the remanent state is understood as referring to a remanent polarization state that is set by applying a particular voltage across the element that is sufficient to set a corresponding polarization state, where, once set, the remanent polarization state is retained by the element even when the voltage across the element has been removed (e.g., it is remanently-polarizable). Once such an element has been state-programmed to a remanent state, it generally retains the programmed state until it is re-programmed by applying a voltage across it that is sufficient to program the element to a (e.g., new) remanent state. A polarization capability of a state-programmable memory element (e.g., remanent polarization capability, e.g., non-remanent spontaneous polarization capability) may be analyzed using capacity measurements (e.g., a spectroscopy), e.g., via a static (C-V) and/or time-resolved measurement or by polarization-voltage (P-V) or positive-up-negative-down (PUND) measurements. Another method for determining a polarization capability of a state-programmable memory element may include transmission electron microscopy, e.g., an electric-field dependent transmission electron microscopy.

As noted above, a memory device (shortly also referred to as memory) includes multiple memory cells, of which each memory cell contains a memory element that represents information by being programmable to different states, each state corresponding to different stored information (e.g., a stored value of a digital bit of “0” may be represented by a first programming state and a digital bit of “1” may be represented by a second programming state). Once the memory element of the memory cell has been programmed (also referred to as write operation), e.g., by initiating a write operation mode, the programmed state may be read out (also referred to as read operation), e.g., by initiating a read operation mode. In the read operation mode, a read voltage may be applied to the memory element that is sufficient to switch its programmed state and develop a charge (also referred to as switching charge) in a cell operation circuit, a sensed voltage of which may then be compared to a threshold reference voltage to determine the programmed state (also referred to as memory state).

As used herein, the term “programming voltage” refers to a voltage across the state-programmable memory element, by which the state-programmable memory element is programmed to a corresponding remanent polarization state. The programming voltage across the memory element used in the write operation (then also referred as to writing voltage) may, in some aspects, differ from the programming voltage in the read operation (then also referred as to read voltage). As is understood, the term “access” with reference to a memory element generally refers to an interaction with the memory element, e.g., including reading from the memory element or writing to the memory element. The related access operation may include various phases (e.g., implemented by an operation schema), e.g., such as addressing the memory element, setting the access operation mode (e.g., writing operation mode of writing operation mode), programming the memory element, sensing one or more voltages indicative of the memory state of the memory element, and the like. As is understood, the term “access circuitry” refers to any implementation, which is configured to access the memory element, e.g., by writing to the memory element or reading from the memory element.

A cell operation circuit, e.g., the access circuitry thereof, may include or may be implemented by a sense circuitry, e.g., a sense amplifier as sense circuitry, to which this disclosure refers to without limitation thereof. It may be understood that all other architectures of cell operation circuits (also referred to as sensing architectures) may be used, to which the references made herein apply in analogy. Various implementations of a cell operation circuit, e.g., the sense amplifier thereof, are configured to amplify a voltage swing initiated by the switching charge to a certain level, which can be interpreted properly by a circuit outside the memory. For example, the sense amplifier may be implemented by a latch, which is described later in detail.

As example, the sense circuitry may, e.g., when being brought into reading operation mode, be configured to sense a voltage response (also referred as to voltage swing voltage or as to state indicative voltage swing) of reading operation applied to the memory element, which develops at an access node (e.g., sensing node) of the access circuitry, and provide, as response thereto, a signal (also referred as to output signal or as to state indicative output signal) indicative of the memory state of the memory element. Alternatively or additionally, the sense circuitry may, e.g., when being brought into writing operation mode, be configured to sense a signal (also referred as to programming selection signal or as to data signal) representing a logic state to be stored at the memory element and provide, as response thereto, a writing voltage capable of programming the memory element in accordance with the logic state.

Various memory architectures seek to reduce the footprint of memory device, e.g., by increasing the area density of the memory elements. One example includes the 3D memory architecture, according to which the memory elements are not only distributed laterally, but also vertically (e.g., over each other). Such implementations may be limited by the maximum area density of the access transistors used for accessing the individual memory elements. Beyond this limit, each access transistor is assigned to a group of memory elements and configured to access each memory element of the group simultaneously. This configuration reduces the electrical separation of the memory elements from each other, thereby increasing the electrical interaction of the group of memory element with each other. This increased interaction increases the risk of disturbance of the memory elements, e.g., the unselected memory elements by the access operation applied to the selected memory element of the group. Various aspects disclosed herein reduce the risk of disturbance, thereby increasing the reliability of the memory device.

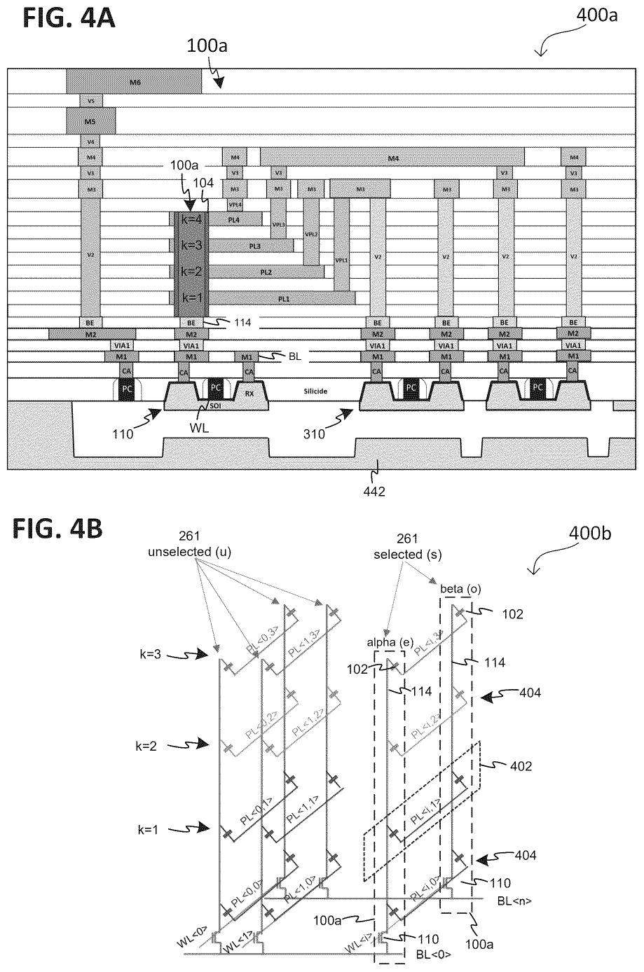

In the following, various aspects of the architecture are detailed, followed by more specific exemplary implementations (see for example, FIG. 4A).

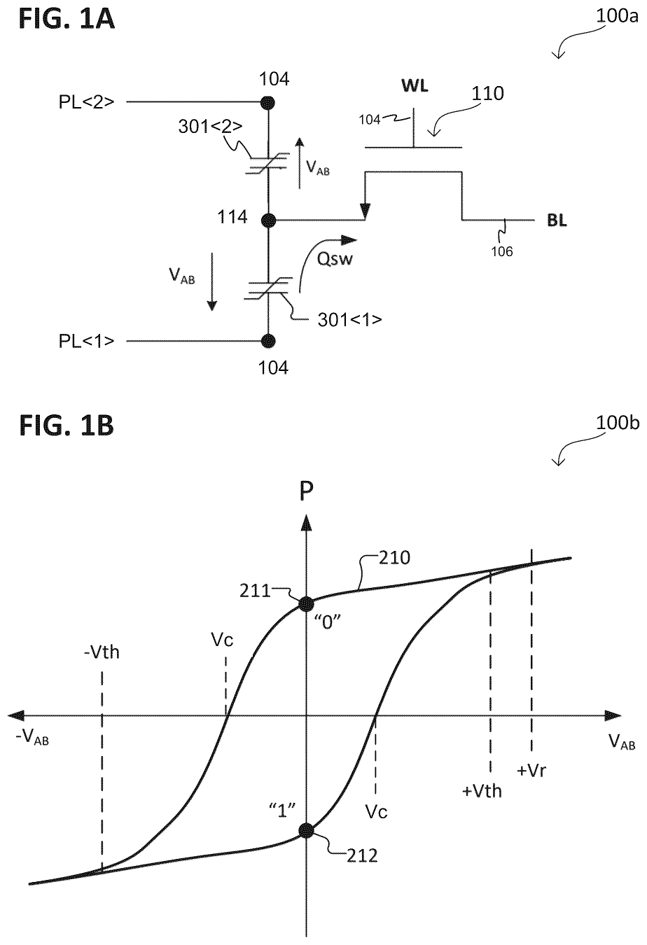

FIG. 1A shows an exemplary memory cell 100a including multiple state-programmable memory elements 301 (also referred as to multi-bit memory cell 100a), referenced by <1> and <2>, and an access switch 110 provided by a transistor (also referred as to access transistor); and FIG. 1B shows a diagram of an exemplary hysteresis curve 210 of such a state-programmable memory element 301 according to various aspects 100b. For facilitated understanding, references made to a single memory element, e.g., in context to architecture and operation, may apply to each of the memory elements 301<k>.

The memory element 301 includes a first terminal 114 (also referred to as access terminal, local access terminal or as to storage terminal), which may be a common terminal for multiple memory elements 301 of the cell. The access terminal 114 is configured to be connected to the bitline (BL) of the memory through a transistor (also referred as to access transistor) implementing the access switch 110. The memory element 301 includes further a second terminal 104 (also referred to as plateline terminal), which is configured to be connected to the plateline (PL) of the memory.

The access switch 110 (e.g., bitline terminal 106 thereof) may be configured to be controlled by a wordline (WL) of the memory, e.g., as the gate of the access transistor is exposed to a voltage of the wordline, WL. The figure illustrates the connection of the memory element 301 to the plateline PL and bitline BL, with the access transistor acting as switch controlled by the wordline WL. When the access switch 110 is active, it allows a switching charge Qsw to be developed onto the bitline BL, causing a voltage swing (also referred as to state indicative voltage swing) at the bitline BL, which is indicative of the programmed state of the memory element 301.

An exemplary implementation of an access operation, a first state-programmable memory element 301<1> of the cell 100a is determined as selected (also referred as to selected memory element) and a second state-programmable memory element 301<2> of the cell is determined as unselected (also referred as to unselected memory element). A protection voltage is provided via the second plateline, PL<2>, to which the unselected memory element 301<2> is exposed, when a switching charge Qsw is provided from the selected memory element 301<1> to the common access terminal 114. As the switching charge Qsw is developed onto the bitline BL, a voltage swing (also referred to as switching voltage) occurs at the bitline BL, which is a function of the programmed state of the selected memory element 301<1> and its dielectric capacitance. The developed switching voltage may be processed by a sense circuitry, which is coupled to BL. For example, the switching voltage is compared to a predetermined threshold voltage to determine the read state (e.g., the logic state, e.g., a “0” or a “1”) of the corresponding memory cell.

Due to the architecture, the unselected memory element 301<2> is also exposed to the switching voltage via the common access terminal 114. The disturbance voltage as resulting voltage V_{AB} across the unselected memory element memory element 301<2> may be a function of (e.g., equaling to) the difference between the protection voltage, PPV, and the switching voltage. The protection voltage, PPV, may be configured such that the risk of the disturbance voltage being capable of changing the memory state of the unselected memory element 301<2> is reduced. For example, the disturbance voltage may be kept below the coercivity voltage, Vc, of the memory element or at least near the coercivity voltage Vc, e.g., in the range Vc±10%.

FIG. 1B shows a schematic diagram 100b of an exemplary hysteresis curve 210 of a state-programmable memory element (e.g., the state-programmable memory element 301 of FIG. 1), where the polarization (P) of the state-programmable memory element is plotted as a function of the voltage applied across it (V_{AB}). In the case of the memory cell shown in FIG. 1A, the voltage applied across the state-programmable memory element is the difference in voltage between the plateline terminal 104 and the access terminal 114, e.g., expressed as a function of V_{PL}-V_{BL}, wherein V_{BL} denotes the bitline voltage. Diagram 100b shows two remanent polarization states (211, 212) of the state-programmable memory element that may represent the programmable states of the memory element. For example, the state-programmable memory element may be programmed to remanent polarization state 211 (representing, for example, a bit of digital information with a value of “0”) or to remanent polarization state 212 (representing, for example, a bit of digital information with a value of “1”) by applying a programming voltage across the state-programmable memory element that is sufficient to program the corresponding remanent polarization state.

The programming voltage defined by a (e.g., intrinsic) threshold voltage, Vth (also referred as to programming threshold), of the state-programmable memory element (e.g., above its coercive voltage), above which the state-programmable memory element is programmed to a corresponding remanent polarization state. For example, if the applied voltage (e.g., programming voltage, e.g., read voltage) across the state-programmable memory element is greater than +Vth (e.g., more positive than +Vth), the state-programmable memory element will be programmed to remanent polarization state 211. If the applied voltage across the state-programmable memory element is greater than-Vth (e.g., more negative than-Vth), the state-programmable memory element will be programmed to remanent polarization state 212. The hysteresis curve 210 shows the path the polarization follows as the voltage across the state-programmable memory element changes.

For example, the disturbance voltage may be kept below half (e.g., a third) of the programming voltage, Vth, or at least near that value (e.g., ±10%).

To read the stored state (also referred to as programmed state) of a state programmable memory element, a read voltage (e.g., +Vr being a function of V_{PL}) is applied across the state-programmable memory element that is sufficient to program a remanent state of the state-programmable memory element to a predefined state. For example, the read voltage may be outside the interval of [−Vth, +Vth]. This develops the switching charge, which is a function of the programmed state before the read voltage was applied. In the first case, when the read voltage causes the state-programmable memory element to switch to a new state (e.g., the predefined state is different from the previously programmed state), the switching charge will be larger compared to the second case, when the read operation caused the state-programmable memory element to be re-programmed to the same state (e.g., the predefined state is the same as the previously programmed state). For example, in the second case, little or no switching charge will be provided from the state-programmable memory element.

According to various aspects, the predefined state is assumed to be “0” herein, which is not limiting, and the references hereto may apply in analogy to a configuration, in which the predefined state is to be “1”, and vice versa.

As should be understood, the voltage of the bitline BL (also referred as to bitline voltage, V_{BL}) may be time dependent and also a function of one or more parasitic (e.g., capacitive) couplings (also referred as to parasitic variance), e.g., the intrinsic dielectric capacitance of the state-programmable memory element 301, the capacitance of the conductors to which it is connected (e.g., the bitline), and the capacitive coupling to one or more other bitline BL and/or the plateline PL. As a result, the voltage, V_{BL}, of the bitline, BL, which is processed by the cell operation circuit during a read operation, may depend not only on the switching charge but also on such capacitive couplings, the voltage level of the plateline and vice versa. The same applies to the effectively applied read voltage, Vr, which may also be a function of such parasitic variance of the bitline voltage, V_{BL}.

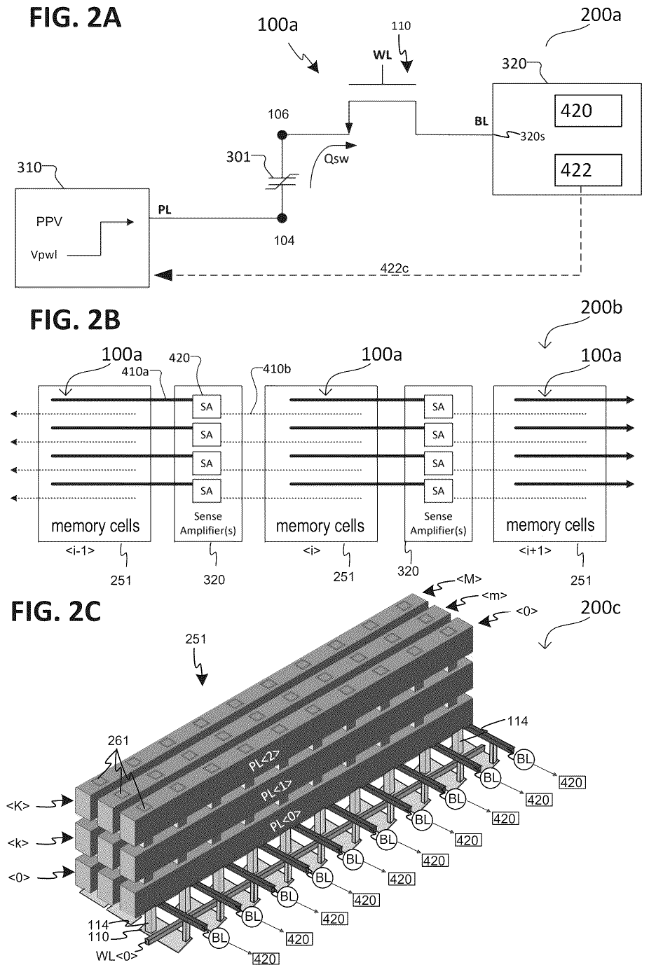

FIG. 2A shows a device 200a (e.g., memory device) in a schematic circuit. Device 200a includes the memory cell 100a, a cell operation circuit 320, the bitline, BL, and a plateline voltage control circuitry 310, coupled to the plateline, PL. The state-programmable memory element 301 connects to the bitline, BL, via an access switch 110 provided by the access transistor and controlled by the wordline, WL.

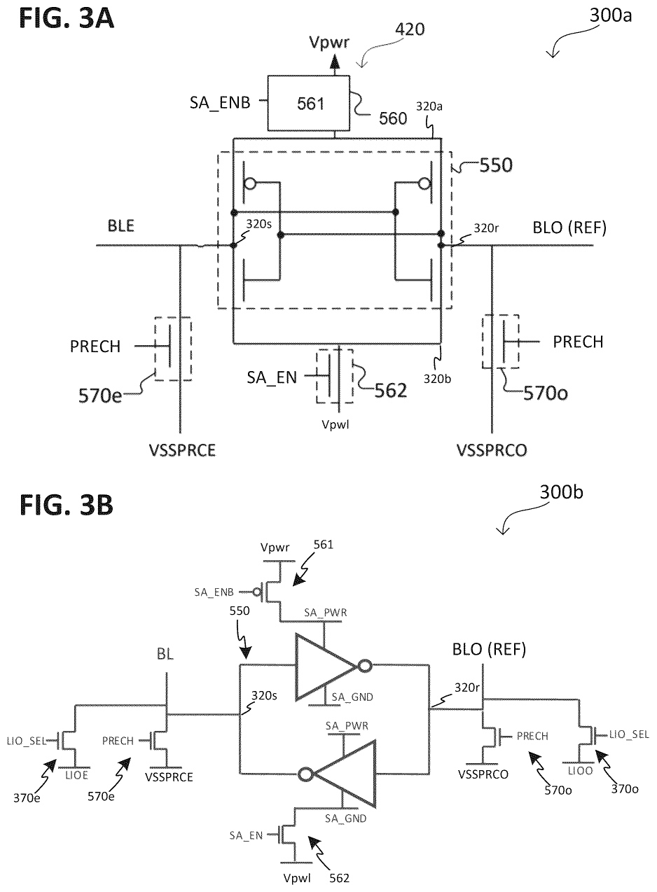

The memory cell 100a includes the memory element 301 being in series between the bitline, BL, and the access switch 110, which is controlled by the wordline, WL. The memory element 301 is coupled via the access switch 110 to an access node 320s (e.g., sensing node) of the cell operation circuit 320, e.g., including a sense amplifier 420 as exemplary access circuitry thereof (see also FIG. 3A) and a control circuitry 422. The control circuitry 422 may be configured to control 422c the plateline voltage control circuitry 310 or implement the plateline voltage control circuitry 310. The memory element 301 is further coupled to the plateline, PL, via the plateline terminal 104 and to the access switch 110 via the access terminal 114 (also referred as to local access terminal or as to storage terminal), which is connected to the access node 320s via the bitline, BL.

The sense circuitry is responsible for reading the programmed state of the memory element 301 by sensing the voltage developed at the access node 320s. The plateline PL is supplied by the plateline voltage control circuitry 310 (also referred as to plate voltage source 310), which provides, as plate voltage, V_{PL}, a lower operation voltage, Vpwl, the protection voltage, PPV, the read voltage, Vr, and the programming voltage VPP. The protection voltage, PPV, may be between the plate voltage, V_{PL}, and the lower operation voltage, Vpwl. Various aspects herein provide, e.g., by the protection voltage and/or an operation schema using the same, a reduction of the risk to disturb unselected pages as detailed later.

In an exemplary read operation, a read voltage is applied to a selected state-programmable memory element 301 (also referred as to selected memory element 301), e.g., by increasing the voltage, V_{PL,} of the plateline, PL, e.g., to +Vr or more. The read voltage is sufficient to program the state-programmable memory element 301 to a predefined remanent state (e.g., the state associated with “0,” e.g., shown in FIG. 1B as 211). The switching charge (Qsw) is then developed by the programmable memory element 301 through the access transistor to the bitline BL.

As should be understood, a single sense amplifier 420 may, for example, be connected to multiple memory elements that are part of the same set and therefore share a common bitline. Alternatively or additionally, a sense amplifier 420 (see also FIG. 3A) may be differential or dual-sided, where one side of the sense amplifier 420 is connected to a bitline of one set of memory cells, which are also referred as to “even” set and “even” bitline for facilitated understanding. The other side of the amplifier is connected to a bitline of a different set of memory cells, which are also referred as to “odd” set and “odd” bitline for facilitated understanding. In a dual-sided configuration, one side of the sense amplifier 420 may be actively operated to read a bitline of one set of cells (e.g., the even side) while the other side (its complement) of the amplifier acts as a reference (e.g., a bitline on the odd side), and vice versa.

To facilitate understanding, the lower operation voltage, Vpwl, e.g., a based state thereof, is herein represented by electrical ground (GND). The references made thereto may be understood as not limiting and to apply in analogy to any other lower operation voltage, which may be different from ground, such as a virtual ground, a negative voltage, a variable lower operation voltage or the like.

FIG. 2B shows a device 200b (e.g., memory device) in a schematic circuit diagram, the device 200b including multiple sets 251 of memory cells 100a, and multiple cell operation circuits 320 in a complementary configuration (also referred to as dual-sided configuration), of which each cell operation circuit 320 includes a set of sense amplifiers (also referred to as bank) coupled to a bitline, BL. The complementary type uses dual-sided (also called complementary) sense amplifiers as shown in FIG. 2B, where each sense amplifier in a set of sense amplifiers may be connected, on one side of the dual-sided amplifier to a common bitline for one row in an “even” set of memory cells (shown by heavy, dark lines) and on the other side of the dual-sided sense amplifier to a common bitline for one row in an “odd” set of memory cells (shown by light, dotted lines). Illustratively, the light line of a given sense amplifier is complementary to the dark line. In FIG. 2B, eight sense amplifiers are shown in two different banks, where one sense amplifier 420 and its complementary “even” bitline 410a connected to one row of an “even” set of memory cells and its “odd” bitline 410b connected to one row of an “odd” set of memory cells are labeled. As should be appreciated, this type of pattern may repeat across the memory, where each memory cell array may have any number of rows of “even” sets of memory cells, each with a (e.g., complementary) row in the set of “odd” memory cells, where each sense amplifier connects, differentially, to an even/odd bitline pair. As should be understood, the terms “even” and “odd” are arbitrary groupings of memory cells to which the sense amplifier is connected and need not refer to any particular numbering scheme of even-and odd-numbered cells. More generally, the even/odd configuration or dual-sided configuration described herein may be understood as a complementary configuration, where one side of the amplifier is the side to be read while the other side serves as its complement. In a typical memory that has even and odd groupings of memory cells, the groupings may be, for example, layout-based.

In an exemplary implementation of device 200b, each sense amplifier is connected to an odd bitline and an even bitline, and e.g., using the odd bitline as a reference bitline and the even bitline as data bitline for sensing the memory state (also referred as to targeted bitline). Further, each set 251 of memory cells 100a provides a memory cell array referenced by an integer <a> (a=1, . . . a=i, . . . a=A), where A is the number of memory cell arrays. In an exemplary first operation scenario of the device 200b of FIG. 2B, the memory cell array <i> (depicted in the center) between two operation circuits 320, of which each includes a set of sense amplifiers 420, is determined as the addressed array (also referred as to selected array). Then, both set of bitlines coupled to the addressed array, a first set of bitlines (dark lines) and a second set of bitlines (dashed lines), are used as targeted bitlines (data bitlines), irrespective of the denotation “even” or “odd”. Further, the dark bitlines 410a coupled to memory cell array <i−1> (leftmost array) and the dashed bit lines 410b coupled to the memory cell array <i+1> (rightmost array) are used as reference bitlines.

In an exemplary second operation scenario, memory cell array <i+1> is determined as the addressed array. Then the dark bitlines coupled to memory cell array <i> are used as reference bit lines, by exposing each thereof to the reference voltage.

In view thereof, it is understood herein, that the references made herein regarding to the terminology “odd” and “even” and to the exemplary operation scenarios, in which the “odd” side is used as reference (see as example FIG. 3A), may apply in analogy to the operation scenarios, in which the “even” side is used as reference. Terminology referring to “odd” and “even”, such as “VSSPRCO”/“VSSPRCE”, may be understood as referring to a specific set of sense amplifiers, and may, in other scenarios, be vice versa. For example, referring to the exemplary first operation scenario detailed above, the sense amplifiers 420 of the left cell operation circuit 320 use the dark bitlines (e.g., even bitlines) as reference bitlines and the dashed bit lines (e.g., odd bitlines) as data bitlines, whereas the sense amplifiers 420 of the right cell operation circuit 320 use the dark bitlines (e.g., even bitlines) as data bitlines and the dashed bit lines (e.g., odd bitlines/cells) as reference bitlines.

FIG. 2C shows a device 200c (e.g., memory device) in a schematic three-dimensional circuit diagram, the device 200c including a set 251 of memory cells 100a. The set 251 of memory cells 100a includes multiple groups 261 (e.g., rows) of memory elements 301 (also referred as to access group 261), of which each group 261 provides one or more memory cells 100a and includes multiple (in this example 3) memory elements 301, e.g., stacked memory elements 301. Device 200c further includes one access switch 110 per group of memory cells, which memory elements 301 are coupled to the bitline, BL, via the access switch 110. Further, each of the memory elements 301 may be coupled to a plateline, PL.

For a facilitated understanding, the memory elements 301 are referenced by a tuple <m, k>. The integer m is in the range from 0 to M referencing the wordline, WL, and the group of memory elements 261 coupled thereto via an access switch. The integer k is in the range from 0 to K referencing the memory elements 261 of each group of memory elements 261, e.g., by referencing a position thereof, e.g., the layer number. For example, the j-th memory element 301 of the i-th group of memory elements 261 is coupled to the wordline <i> and referenced as memory element <i, j >.

The operation circuit 320 includes a set of sense amplifiers 420 to read the programmed state of the memory cells 100a based on the voltages developed at the access nodes 320s. For example, the memory cells 100a are arranged in rows and columns within a memory cell arrays, with each row connected to a common wordline WL and each column connected to a common bitline BL.

FIG. 3A shows a part of cell operation circuit 320 of a complementary type including a sense amplifier 420 in a schematic circuit diagram 300a. In a dual-sided configuration, the sense amplifier may be implemented by a latch 550. The latch 550 of the exemplary dual-sided configuration includes the access node 320s as first input (e.g., the “even” input) connected to an even bitline (BLE) and a further access node 320r (also referred as to reference access node) as a second input (e.g., the “odd” input) connected to an odd bitline (BLO). As detailed above, the references made hereto are related to the exemplary first operation scenario, and may apply in analogy to other operation scenarios, in which the odd bitlines are used as data bitlines. The latch 550 may be powered via one or more switches 561, 562 (also referred to as circuit operation switches 561, 562), e.g., transistors, of an operation control circuitry 560. The operation control circuitry 560 may be controlled by one or more operation sense enable signals, SA_EN, SA_ENB, provided to or by a control circuitry, as described later in detail. As example, SA_ENB may be a function of SA_EN (e.g., generated based on SA_EN) e.g., as an inverse signal of SA_EN.

The circuit operation switches 561, 562, when enabled, connect a first side of the latch 550 to a first operation voltage (also referred as to supply operation voltage or as to upper operation voltage), Vpwr, supplied to the first input terminal 320a (also referred as to SA_PWR), and a second side of the latch 550 to the lower operation voltage, Vpwl (e.g., ground or another lower operation voltage) supplied to a second input terminal 320b (also referred as to SA_GND). The supply operation voltage may be more than the lower operation voltage, e.g., by at least about 1 Volt, e.g., by at least about 2 Volt, e.g., by at least about 3 Volt, e.g., by at least about 4 Volt.

To initiate a read operation mode, the circuit operation switches 561, 562 may be operated by the one or more sense enable signals (also referred as to SE signals) to expose the latch 550 to the operation voltages, Vpwr and Vpwl, e.g., when a first SE signal, SA_EN, is enabled. Before and/or after the read operation mode, the circuit operation switches 561, 562 may be operated by the one or more SE signals to leave the latch 550 floating (also referred to as inactive latch 550), when the first SE signal, SA_EN, is not enabled.

Even and odd pre-charging control (PRC) switches (570e, 570o), e.g., implemented by respective transistors (also referred as to PRC transistors), may be operated by a single corresponding signal (PRECH) that, when enabled, causes the corresponding bitline to be connected to its corresponding even/odd pre-charging source voltage (VSSPRCE, VSSPRCO) for charging and/or discharging the corresponding bitline. As reflected by the exemplary implementation of FIG. 3A, the PRC transistors 570e, 570o may share their gate control line, thus being exposed to the same PRC (pre-charge control) signal (also referred as to PRECH). Further, the pre-charging source voltages used for biasing the bitlines, BLO/BLE, may be provided individually, e.g., providing an even pre-charging source voltage, VSSPRCE, used for biasing the even bitline (BLE), and an odd pre-charging source voltage, VSSPRCO, used for biasing the odd bitline (BLO). For example, the level of each bias volta pre-charging source voltage (VSSPRCE, VSSPRCO) may be controlled by pre-charge signal control circuitry (not detailed). The pre-charge signals (VSSPRCE, VSSPRCO) may be controlled to be at the first pre-charge voltage, e.g., Vpwl, or a second first pre-charge voltage, VREF.

As detailed above, the references made to the even/odd pre-charge signals (VSSPRCE, VSSPRCO) are related to exemplary operation scenarios. Generally, the pre-charge signals (VSSPRCE, VSSPRCO) may be provided as global signals, i.e. which are not exclusively assigned to a specific bit line. Each bitline is exposed to either VSSPRCE or VSSPRCO, depending on the operation scenario and on the respective switch(es) activated.

FIG. 3B shows a part of cell operation circuit 320 of a complementary type including a sense amplifier 420 in a schematic circuit diagram 300b, being similar to circuit diagram 300a.

The sense amplifier 420 comprises two cross-coupled inverters, of which each inverter is powered by the supply operation voltage, Vpwr, and the lower operation voltage, Vpwl. Additionally to circuit diagram 300b, each of the complementary input nodes 320s, 320r (also referred as to access node 320s and reference access node 320r) is coupled to a data transfer switch 370e and 370o, respectively (e.g., implemented by transistors), which are controlled by a data transfer control signal, LIO_SEL, to expose the bitline to a data transfer terminal, namely LIOE (even) and LIOO (odd), respectively. It is understood that the data transfer switches 370e and 370o, may, in the write operation, be used to transfer data from the data transfer terminal to the sense amplifier 420, and in the read operation, be used to transfer data from the sense amplifier 420 the data transfer terminal.

In both embodiments according to diagrams 300a and 300b, the sense amplifier 550 is configured to amplify the small voltage difference between the bitlines BL and BLO during an access operation, which allows reading from or write to a memory element. The pre-charging switches 570e, 570o are configured to set the voltage of each bitline, BL and BLO, to a known voltage before the access operation is initiated. The SE signals, SA_ENB, SA_EN, are configured to activate and deactivate of the sense amplifier 550 in accordance with the operation schema.

FIG. 4A illustrates a schematic cross-sectional view of a memory device according to various aspects 400a, detailing the layer architecture of the memory device. The memory device is formed on a substrate 442 (e.g., a wafer) and includes multiple stacked (e.g., dielectric) layers, embedding multiple metallization lines, Mx (wherein “x” references the vertical position thereof), multiple vias, VIAx (wherein “x” references the vertical position thereof), multiple vertical connectors, Vx (wherein “x” references the vertical position thereof), multiple platelines, PLx (wherein “x” references the vertical position thereof), multiple terminals, CA, BE, and a stack of memory elements, <k> (referenced by “k” in accordance with the vertical position thereof), wherein k=1 to k=4.

An exemplarily implementation of the stack of memory elements, <k>, is monolithically coupled with each other. For example, the memory cell 100a includes a monolithic polarizable column, which provides each of the stack of memory elements of the memory cell 100a. Optionally, the polarizable column may be embedded into a monolithic tube-shaped electrode providing for the plateline terminals 104 adjoining the individual memory elements. Further, the memory cell 100c includes one access terminal 114, which is coupled to the stack of memory elements, <k>.

The memory device includes, per memory cell 100a, one access switch 110, which is coupled via the access terminal 114 of the cell to the stack of memory elements (e.g., ferroelectric memory elements, FeCap). The multiple platelines, PL(x=k*), may include one plateline, PL, per memory element k=k* of the stack of memory cells <k>. The plateline voltage control circuitry 310 includes multiple switches (also referred as to PCV switches), e.g., implemented by transistors. The PCV switches may include at least one PCV switch per plateline, PLx.

Such architecture (also referred as to 3D memory architecture) based on stacked memory cells is very compact, thereby reducing footprint of the memory cell 100a and reducing other cost-driving parameters. For example, the 3D memory architecture may fit multiple bits in the footprint of a single conventional cell.

An exemplarily implementation of the memory cell 100a includes a stack of memory cells <k>, which is coupled galvanically with each other, and each memory element thereof is connected to the access switch (e.g., source/drain thereof), which is controlled by a common wordline, WL. As result thereof, the stack of memory elements interacts with each other during operation (e.g., read operation or write operation), thereby disturbing each other (also referred as to parasitic disturbance). For example, one or more unselected memory elements on the common (local) bitline may experience a disturbance during the read operation and write operation, since there is no access transistor for each of the one or more memory elements to isolate the unselected memory elements from the selected memory cell. This parasitic disturbance may lead to a risk, that one or more unselected memory element of the stack of memory elements may change its programmed state (also referred as to re-programming), e.g., from “0” to “1” or vice versa, and thus may lead to reliability issues.

Various aspects detailed herein address the parasitic disturbance of multiple memory elements, The references made hereto may apply to any other memory architecture being subject to a parasitic disturbance, which is not necessarily limited to a stacked memory elements or 3D architecture. Various aspects detailed herein provide a control scheme of the memory device to lower the parasitic disturbance, thereby increasing the reliability of the memory device. It may be understood that the references made to the memory elements (k=1 to k=4) may apply in analogy to a larger or smaller number of stacked memory elements. It may be understood that the references made to the stacked memory elements may apply in analogy to any other memory architecture, by which multiple memory elements may be addressable via the same access switch.

FIG. 4B shows a memory device in a schematic circuit diagram according to various aspects 400b in complementary configuration, detailing the logical arrangement of wordlines and bitlines within the memory device. As understood herein, the memory cell 100a may include multiple (e.g., stacked) memory elements and one access switch 110, by which the multiple (e.g., stacked) memory elements are coupled to a bit line, BL.

To facilitate the understanding, and easily distinguish between the even components, the terminology “alpha” (denoted by (e)) and “beta” (denoted by (o)) is used without being limiting or indicating any order or preference.

In a complementary configuration, each access group 261 may include a pair of memory cells 100a (then also referred as to complementary cells 100a), which are assigned to each other, thereby providing multiple pairs of complementary memory elements 301 (for facilitated understanding, also referred as to memory pages). Each memory page (pair of complementary memory elements 301) includes a first (e.g., alpha) memory element 301(e) of a first of complementary cells 100a and a second (e.g., beta) memory element 301(o) of a second of the complementary cells 100a.

In analogy to aspects 200c, the memory pages are referenced by a tuple <m, k>. The integer m is in the range from 1 to M referencing a pair of complementary cells 100a. The integer k is in the range from 0 to K referencing the memory elements of each memory cell 100a, e.g., in accordance to the vertical position thereof. For example, the j-th memory page of the i-th pair of complementary cells 100a is coupled to the wordline <i> and referenced as page <i, j >. The pair (e.g., alpha and beta) of complementary memory elements 301 of a page <i, j> are coupled to each other by a respective plateline, PL<i, j> (also referred as to page plateline).

The operation schema may include to determine (e.g., select) a complementary pair 402 of memory elements 301 (also referred as to selected pair or to selected page 402) of an access group 261 (then also referred as to selected access group 261(s)) to be accessed, e.g., to be read and/or be written. As response to being accessed, a switching charge is developed at each respective access terminal 114 of the selected pair of complementary cells 100a, thereby initiating a voltage swing at the access terminals 114. For example, a first voltage swing is developed at the alpha access terminal 114(e), to which each alpha memory element 301(e) of the selected access group 261(s) is exposed. In analogy, a second voltage swing is developed at the beta bitline terminal 114(o), to which each beta memory element 301(o) of the selected access group 261(s) is exposed.

According to various aspects, it was recognized that the memory elements 301 of unselected pages 404, which are coupled to a selected page 402 via a common access terminal 114 (also referred as to local bitline), may experience a disturbance during an access (e.g., read or write) operation of the selected page 402, since there is no electrical separation (e.g., access transistor) for each memory element 301 (e.g., FeCap) to isolate the unselected pages 404 from the selected page 402. This disturbance may cause reliability issues resulting in flipping of memory elements from one memory state to the other.

Various aspects herein provide, e.g., by a protection voltage and/or a respective operation schema, a reduction of the risk to disturb unselected pages, e.g., to a level being sufficiently low to guarantee the target reliability of the memory device.

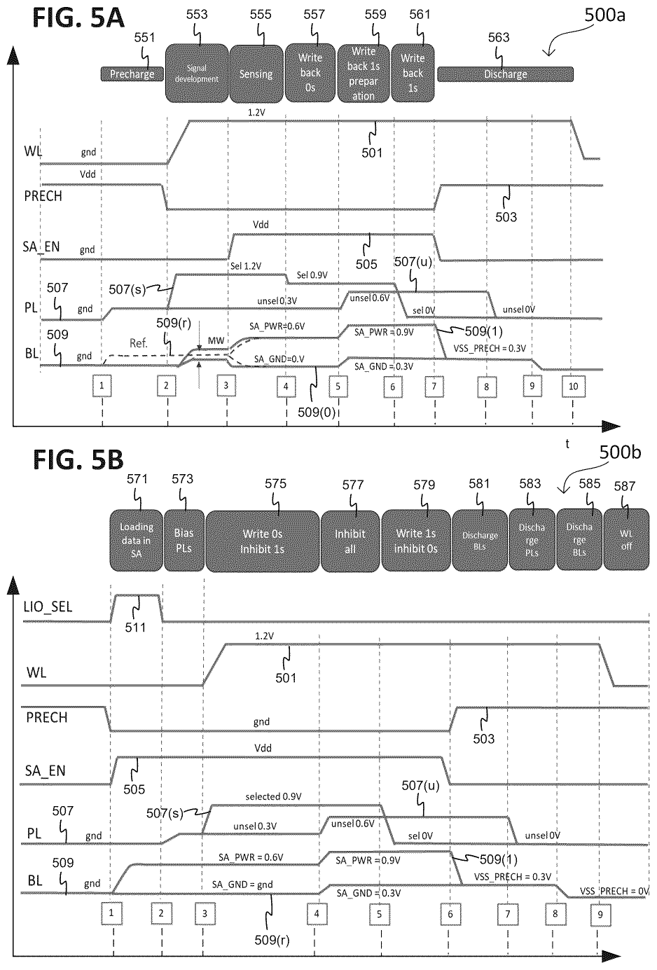

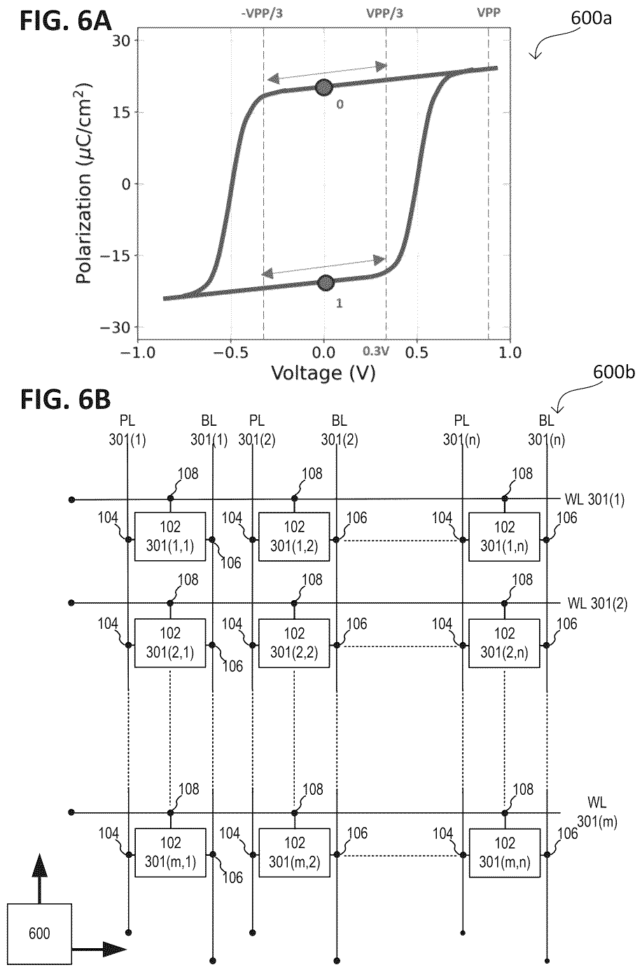

FIG. 5A shows an operation schema in a schematic diagram according to various aspects 500a for the cell operation circuit 320, e.g., detailing the time dependency or various signals during a read operation, including the time dependency of:
the voltage at the wordline, WL<i>, represented by line 501,
the pre-charge control signal (PRECH), represented by line 503,
the operation enable signals, SA_EN, represented by line 505,
the voltage at the plateline, PL, represented by line 507 for two memory pages of a selected access group 261(s), of which a selected page 402 is coupled to a selected plate line, PL<i, 1>, represented by line 507(s) and each unselected page 404 is coupled to an unselected plate line, PL<i, 0>, PL<i, 2>, PL<i, 3>, represented by line 507(u),
the voltage at the bitlines, BL<0>, BL<n>, represented by line 509, which are coupled to the access switches 110 of the selected memory cells 100a, e.g., the bitline terminal 114 thereof.

It may be understood that the references made thereto for the alpha and beta memory cells 100a of the selected group 261(s) are exemplary and may in analogy apply vice versa. For this example, both (alpha and beta) memory elements of the selected page 402 may be read simultaneously. The alpha memory cell 100a may be connected by bitline, BL<0>, to a first sense amplifier 420. The beta memory cell 100a may be connected by bitline, BL<n>, to a second sense amplifier 420. The reference voltage, represented by line 509(r), may be applied to each of the first and second sense amplifiers 420 (e.g., to the odd side thereof through transistor 570o). It may be understood that the reference voltage, represented by line 509(r), may be provided, e.g., by charging the access reference node of the sense amplifiers 420 to a respective pre-charge voltage as reference.

For a facilitated understanding, the memory elements of the selected page 402 are programmed differently to reflect the signal development for different memory states, for which:
the alpha bitline, BL<0>, is represented by line 509(1) and relates to the alpha memory element 301(e, s) of the selected page 402 being in a first memory state (e.g., representing logical “1”), and
the beta bitline, BL<n>, is represented by line 509(0) and relates to the beta memory element 301(o, s) of the selected page 402 being in a second memory state (e.g., representing a logical “0”),
   The references made hereto may apply, in analogy, to equally programmed memory elements of the selected page 402.

The read operation includes multiples phases, which are detailed in the following. The read operation starts with a first phase 551 (also referred as to pre-charge phase) at t=1, at which the pre-charge control signal, PRECH, plotted along line 503, is at logic high, thereby connecting the respective bitline to VSSPRCE/VSSPRCO. In the pre-charge phase, each memory element of the selected access group 261(s) is exposed to the protection voltage (here as example 0.3 Volt), e.g., by charging the respective platelines. For example, the voltage across the selected beta memory element 301(o,s) may, in the pre-charge phase, be equal to the voltage across the selected alpha memory element 301(e,s).

For example, the voltage, to which each memory element of the selected group 261(s) may be exposed via the respective plateline, PL, may be increased in the pre-charge phase, while the word line, WL, is set to low and/or while the access terminals 114 are floating. For example, the voltage swing of the access terminal is determined by the ratio between the capacitance of the memory element, and the local bitline parasitic capacitances times the voltage at the plateline.

The pre-charge phase ends by changing the pre-charge control signal, PRECH, to logic low, which leaves the bitlines floating.

A subsequent second phase 553 (also referred as to signal development phase) of the read operation starts at t=2 with setting the wordline, WL, to logical high, thereby coupling the alpha access terminal 114(e) to the alpha bitline (e.g., BL<0>), and coupling the beta access terminal 114(o) to the beta bitline (e.g., BL<n>). Further in the signal development phase, the memory elements of the selected page 402 are exposed to a read voltage (here 1.2 V as example) as plate voltage, VPL, supplied to the selected plateline, PL (e.g., plateline <i,1>). This causes an access voltage of the read operation (also referred as to sensing voltage) to develop at each of the bitlines, which is at one of the following two states: logic high for the alpha bitline, BL<0> and logic low for the beta bitline, BL<n>. As example, the reference voltage is between the logic high and logic low of the sensing voltage. The read voltage may be above the threshold voltage, Vth, e.g., above the programming voltage VPP.

A subsequent third phase 555 (also referred as to sensing phase) of the read operation starts at t=3 and with setting the operation enable signal, SA_EN, to logic high. This activates the access circuitry (e.g., sensing amplifier) by supplying the supply operation voltage, Vpwr, to the first input terminal 320a of the access circuitry, and supplying the lower operation voltage, Vpwl, (e.g., ground or another lower operation voltage) the second input terminal 320b of the access circuitry.

The access circuitry is configured to provide, for the alpha bitline, BL<0>, a high voltage level (here 0.6 Volt as example) associated with the first logic state, and for the beta bitline, BL<n>, a low voltage level (here vpwl as example) associated with the second logic state as the programmed state. In the example of the complementary sense amplifier 420, the voltage difference between the complementary input nodes 320s, 320r (also referred as to access 320s node and reference access node 320r) is amplified, e.g., thereby modifying the access voltage at the respective bitline based on the difference between the access voltage and the reference voltage 509(r).

It is noted that, in the second and third phases, the memory elements 301of each unselected page 404 are exposed to a level of the sense voltage developed at the respective bitline, which, may be for the alpha bitline, BL<0> (here 0.6 V as example) above that for the beta bitline, BL<n>. As example, the sense voltage developed at the alpha bitline, BL<0> may be equal to the supply operation voltage. The risk of disturbing the unselected memory elements 301 by such voltage level is reduced by the protection voltage, to which the memory elements 301 of the unselected pages are exposed via the respective platelines, PL. In the numerical example here, the protection voltage is 0.3 V, thereby reducing the maximum voltage across the memory elements 301 of the unselected pages to 0.3 V.

Expressed more general, the risk of disturbance is reduced by setting the protection voltage to a level (also referred to as a protection level), which is between upper and lower occurring voltage extrema, to which the memory elements 301 of the unselected pages may be exposed via the bit line terminal 114. The voltage extrema may depend on the specific configuration of the memory device. Examples of the upper and lower occurring voltage extrema include:
the supply operation voltage (e.g., as upper voltage extrema) and the low operation voltage (e.g., as lower voltage extrema), e.g., GND,
the increased access voltage developed at the alpha bitline, BL<0> (e.g., as upper voltage extrema) and the decreased access voltage at the beta bitline, BL<n> (e.g., as lower voltage extrema).

It is noted that the protection level is not necessarily time-invariant and/or identical to the mean of the two voltage extrema. In some aspects, the protection level differs from phase to phase and/or differs, in each phase, from each of the two voltage extrema by a reliability value, which may be ⅓ of the write voltage or less, e.g., ⅓ of the programming threshold or less.

In case, the read operation is destructively, the programmed state as read (also referred as to read programmed state) from the memory elements 301 of the selected page 402 may be reinstated. In this case, the read operation may include, e.g., subsequent to the sensing phase, a writing sequence based on the result of the sensing phase (also referred as to re-write sequence), e.g., based on the read programmed state. The re-write sequence may be understood as a type of write operation, which is based on the result of the sensing phase, e.g., re-writing the sensed memory state.

The re-write sequence may include a fourth phase 557 (also referred as to first re-write phase) of the read operation starting at t=4, in which the memory elements of the selected page 402 are exposed to the read voltage (here 0.9 V as example) as plate voltage, VPL, supplied to the selected plateline, PL (e.g., plateline <i,1>). The first re-write phase 557 allows to write a logic “0” to the beta memory element 301 of the selected page 402. The access circuitry is in a first write operation mode during the first re-write phase.

The re-write sequence may include a fifth phase 559 (also referred as to) of the read operation starting at t=5, in which the supply operation voltage and the lower operation voltage are increased by an operation voltage swing, e.g., by 0.3 V. This develops a similar increase at the bitlines, e.g., by the operation voltage swing. To compensate for this change, the protection voltage is increased by the operation voltage swing. As result, the protection voltage maintains between the two possible voltage extrema (here 0.3 V and 0.9 V) in the re-write preparation phase 559.

The re-write sequence may include a sixth phase 561 (also referred as to second re-write phase) of the read operation starting at t=6, in which the memory elements of the selected page 402 are exposed to a write bias voltage (here 0 V as example) as plate voltage, VPL, supplied to the selected plateline, PL (e.g., plateline <i,1>). The operation voltage swing and the write bias voltage may be configured such that the difference between the voltage at the alpha bitline and the selected plateline may be equal to the read voltage (here 0.9 V as example) or be higher than the read voltage. The second re-write phase 561 allows to write a logic “1” to the alpha memory element 301 of the selected page 402. The access circuitry is in a second write operation mode during the second re-write phase, which differs from the first write operation mode by the level of one or more of: the lower operation voltage or the supply operation voltage.

The read operation may further include a seventh phase 563 (also referred as to discharge phase) starting at t=7, in which all signals are brought into the state at the beginning of the read operation. For example:
at t=7, the bitlines, BL<0> and BL<1>, may be discharged to VSSPRECH=0.3V,
at t=8, the plateline, PL, may be discharged,
at t=9, VSSPRECH and SA_GND are set to GND,
at t=10, the wordline, WL, is discharged.

The discharge phase ends at t=10 with setting the wordline, WL, to logic low. Thereby the read operation ends.

Expressed more general, the protection voltage facilitates to lower the voltage across the memory elements 301 of the unselected pages, e.g., to a value of VPP/3.

An exemplarily implementation of the read operation includes:
At t=1: set selected and unselected platelines to 0.3V as protection voltage, while the access terminal 114 is floating. This causes the access terminal 114 to follow the voltage swing at the plateline, PL. The voltage at the reference access node is passed through VSSPRECHO.
At t=2: End of Pre-charge phase; set the wordline to logic high and set the selected platelines to the access voltage (e.g., 1.2 V).
At t=3: Set the SE signal to logic high, set PWR=0.6V, and set the SA_GND=0, which allows to read from the selected page.
At t=4: Set the selected plateline to 0.9V, which allows to initiate the re-write (also referred as to write back) sequence.
At t=5: Set SA_PWR=0.9V, set SA_GND=0.3V, and set the unselected plateline to 0.6V.
At t=6: Set the selected plateline to GND (e.g., by discharging), which allows to program the memory elements 301 based on the read programmed state.
At t=7: Discharge the bitlines to VSSPRECH=0.3V.
At t=8: Discharge the unselected platelines, PL.
At t=9: Set VSS_PRECH and SA_GND to 0 V (e.g., GND).
At t=10: Discharge the wordlines, WL.

FIG. 5B shows an operation schema in a schematic diagram according to various aspects 500b for the cell operation circuit 320, similar to aspects 500a, e.g., detailing the time dependency or various signals during a write operation.

The write operation includes multiples phases, which are detailed in the following. The write operation starts with a first phase 571 (also referred as to data loading phase) at t=1, in which a data transfer control signal, LIO_SEL, plotted along line 511, is set to logical high to expose the bitlines to the respective data transfer terminals, namely LIOE or LIOO. In the depicted scenario, the alpha data transfer terminal, e.g., LIOE, of first sense amplifier 402 is at logical high (e.g., representing a digital bit of “1” as data) and the beta data transfer terminal, e.g., LIOO, of second sense amplifier 402 is at logical low (e.g., representing a digital bit of “0” as data). This develops the high voltage level (here 0.6 Volt as example) at the alpha bitline, BL<0>, and the low voltage level (here GND as example) at the beta bitline, BL<n>. For example, the latch of each sense amplifier is loaded by differential signals, LIOE and LIOO. If even bits are to be written and LIOE is at logic high, a digital bit of 1 is written to the memory element.

A subsequent second phase 573 (also referred as to bias PL phase) of the read operation starts at t=2, in which each memory element of the selected access groups 261(s) is exposed to the protection voltage (here as example 0.3 Volt), which is supplied to the respective platelines, PL.

A subsequent third phase 575 (also referred as to first write phase) of write operation starts at t=3, in which the memory elements of the selected page 402 are exposed to the read voltage (here 0.9 V as example) as plate voltage, VPL, supplied to the selected plateline, PL (e.g., plateline <i,1>). Further the wordline, WL, is set to logical high, thereby coupling the alpha access terminal 114(e) to the alpha bitline (e.g., bitline <0>), and coupling the beta access terminal 114(o) to the beta bitline (e.g., bitline <n>). As detailed above, the alpha access terminal 114(e) may be coupled to the first sense amplifier and the beta access terminal 114(o) may be coupled to the second sense amplifier. The first write phase 575 allows to write a logic “0” to the beta memory element 301 of the selected page 402, while inhibiting logic “1”. The access circuitry is in a first write operation mode during the first write phase.

A subsequent fourth phase 577 (also referred as to intermediate phase) of the write operation starts at t=4, in which the supply operation voltage and the lower operation voltage are increased by the operation voltage swing, e.g., by 0.3 V. This develops a similar increase at the bitlines, e.g., by the operation voltage swing. To compensate for this change, the protection voltage is increased by the operation voltage swing. As result, the protection voltage maintains between the two possible voltage extrema (here 0.3 V and 0.9 V) in the inhibit phase 577.

It is noted that, in the fourth phase, the alpha memory elements 301 of the unselected pages 404 are exposed to the voltage developed at the alpha bitline, which reaches a high voltage level (here 0.6 V as example), e.g., equal to the supply operation voltage. The risk of disturbing the memory elements 301 of the unselected pages 404 by such voltage is reduced by the protection voltage, to which the memory elements 301 of the unselected pages 404 are exposed via the respective unselected platelines, PL<i,0>, PL<i,2>, PL<i,3>. In the numerical example here, the protection voltage is 0.3 V, thereby reducing the maximum voltage difference, to which the memory elements 301 of the unselected pages are exposed, to 0.3 V.

Expressed more general, the risk of disturbance is reduced by setting the protection voltage to a level (also referred as to protection level), which is between upper and lower occurring voltage extrema, to which the memory elements 301 of the unselected pages may be exposed via the bit line terminal 114. The voltage extrema may depend on the specific configuration of the memory device. Examples of the upper and lower occurring voltage extrema a include:
the supply operation voltage (e.g., as upper voltage extrema) and the lower operation voltage (e.g., as lower voltage extrema), e.g., GND,
the high access voltage (e.g., as upper voltage extrema) developed from the data transfer terminal for a programming a first state and the low access voltage (e.g., as lower voltage extrema) developed from the data transfer terminal for programming a second state.

It is noted that the protection level is not necessarily time-invariant and/or identical to the mean of the two voltage extrema. In particular for a writing operation, the protection level changes when entering the intermediate phase. For example, the protection level differs, in each phase, from each of the two voltage extrema by a reliability value, which may be ⅓ of the read voltage or less, ⅓ of the programming threshold or less.

A subsequent fifth phase 579 (also referred as to second write phase) of the write operation starts at t=5, in which the memory elements of the selected page 402 is exposed to a write bias voltage (here 0 V as example) as plate voltage, VPL, supplied to the selected plateline, PL (e.g., plateline <i,1>). The operation voltage swing and the write bias voltage may be configured such that the difference between the voltage at the alpha bitline and the plateline may be equal the read voltage (here 0.9 V as example) or be more than the read voltage (here 0.9 V as example). The write phase 579 ends with setting the operation enable signal, SA_EN, to logic low to let the access circuit float. The second write phase 579 allows to write a logic “1” to the alpha memory element 301 of the selected page 402, while inhibiting logic “0”. The access circuitry is in a second write operation mode during the second write phase, which differs from the first write operation mode by the level of one or more of: the lower operation voltage or the supply operation voltage.

A subsequent fifth phase 581 (also referred as to discharge BL phase) of the write operation starts at t=6, in which the alpha bitline is discharged to VSSPRECH=0.3V.

A subsequent sixth phase 583 (also referred as to discharge PL phase) of the write operation starts at t=7, in which the platelines are discharged, e.g., to GND.

A subsequent seventh phase 585 (also referred as to further discharge BL phase) of the write operation starts at t=8, in which the bitline are discharged, e.g., to GND.

A subsequent eighth phase 587 (also referred as to WL deactivation phase) of the write operation starts at t=8, in which the wordline, WL, is set to logic low. Thereby the write operation ends.

An exemplarily implementation of the write operation includes:
At t=1: Prepare the access circuit for programming by setting LIO_SEL and SA_EN to logical high,
At t=2: Set the unselected plateline to 0.3V,
At t=3: Set the wordline to logical high and the selected plateline to 0.9V allowing to write logical “0” to the memory elements with the bitline being grounded. The unselected memory elements coupled to that are exposed to a plate voltage of 0.3 V. The bitlines prepared for writing a “1” are at 0.6V, which allows them to be inhibited at the protection voltage of VPP/3.
At t=4: Set SA_PWR to 0.9V, and SA_GND to 0.3V, and the unselected plateline to 0.6V.
At t=5: Discharge the selected plateline, and write the logic “1” while inhibiting the memory elements 301 programmed state at logical “0”.
At t=6: Discharge the bitlines to VSS_PRECH=0.3V.
At t=7: Discharge the unselected plateline.
At t=8: Set VSS_PRECH and SA_GND to 0 V.
At t=9: Discharge the wordlines.

FIG. 6A shows a diagram of an exemplary hysteresis curve 210 of such a state-programmable memory element 301 according to various aspects 600a, similar to aspects 100b. An exemplarily implementation of the protection level is a third of VPP, wherein VPP denotes the used programming voltage across the memory element 301, at which the memory element 301 may be programmed (e.g., written or re-written). The value of VPP may be in the range from Vth to the read voltage, e.g., being 0.9 V in this numerical example in which the protection voltage is 0.3 V.

More general said, the voltage V_{AB} across a memory element may be expressed as V_{AB}=f(VPL−V_{BL}). When V_{BL}=V_{BL}(t) is time, t, dependent, the protection level supplied as V_{PL} may be adapted to the time dependent value of V_{BL}, e.g., such that V_{AB}(V_{BL})≤VPP/2, e.g., V_{AB}(V_{BL})≤VPP/3. It may be understood, that other numerical values may apply for other cell architectures.

FIG. 6B shows a detailed schematic view on an exemplary memory cell arrangement 600b of a memory device including a plurality of memory cells 102, of which each memory cell 120 includes multiple memory elements 301(k=1 to K, m=1 to M, n=1 to N), and of which each memory cell may be configured, for example, in analogy to memory cell 100a. The view represents the memory elements for which “k=1”, e.g., the base layer of a 3D memory architecture. For each memory element 301(k=1, m=m*, n=n*) as depicted, one or more not shown memory cells 301(k=2 to K, m=m*, n=n*) may be present, which are stacked on top of base layer and are coupled to the access terminal 114(m=m*, n=n*) via the memory element 301(k=1, m=m*, n=n*). It is understood that the memory cell arrangement 600a serves as an example to illustrate the aspects detailed herein and that the reference made thereto may apply in analogy to a memory device in any other suitable configuration.

A memory cell arrangement is usually configured in a matrix-type arrangement, wherein columns and rows define the addressing of the memory cells according to the control lines connecting respectively subsets of memory cells of the memory cell arrangement along the rows and columns of the matrix-type arrangement. However, other arrangements may be suitable as well. In general, a memory cell arrangement may include a plurality of (e.g., volatile or non-volatile) memory cells, which may be accessed individually or on groups via a corresponding addressing scheme. The matrix architecture may be, for example, referred to as “OR”, “AND”, “NOR”, or “NAND” architecture, depending on the way neighboring memory cells are connected to each other, i.e., depending on the way the terminals of neighboring memory cells are shared, but are not limited to these two types (another type is for example an “AND” architecture). For example, in a NAND architecture the memory cells may be organized in sectors (also referred to as blocks) of memory cells, wherein the memory cells are serially connected in a string (e.g., source and drain regions are shared by neighboring transistors), and the string is connected to a first control line and a second control line. For example, groups of memory cells in a NAND architecture may be connected in series with one another. In a NOR architecture the memory cells may be connected in parallel with one another. A NAND architecture may thus be more suited for serial access to data stored in the memory cells, whereas a NOR architecture may be more suited for random access to data stored in the memory cells.

According to the 3D architecture, the memory elements 301(k=1 to K, m=1 to M, n=1 to N) may be arranged an array of K times N times M. Each of “N”, “M” and “K” may be any integer number equal to or greater than one. As example, K may be less than 10. In some aspects, the memory cell arrangement may be in a ferroelectric random-access memory (FeRAM) configuration.

The depicted architecture of memory cell arrangement 600b is understood as exemplary implementation for a facilitated understanding, not meant to be limiting. The referenced made hereto may apply in analogy to other architectures of a memory cell arrangement, e.g., including multiple platelines, e.g., of which the number may range from 1 to N·M·K depending on the chosen architecture. Examples of the number, N_PL, of platelines for implementing an architecture including m wordlines and n bitlines, may include: N_PL=1 (one plateline), N_PL=n, N_PL=m, N_PL=(N·M·K) or combinations thereof. The same applies to other memory cell arrangements as detailed herein in analogy.

The memory cell arrangement may include a plurality of bitlines BL(n=1 to N), at least one plateline PL, and a plurality of wordlines WL(m=1 to M) for (individually and selectively) addressing the plurality of memory cells 301(k=1 to K, m=1 to M, n=1 to N). Each memory element 301(k=k*, m=m*, n=n*) may be connected to and selectively addressable via a corresponding bitline BL(n=n*) of the plurality of bitlines BL(n=1 to N), a corresponding wordline WL(m=m*) of the plurality of wordlines WL(m=1 to M), and the corresponding plateline PL(k=k*, m=m*, n=n*). The *-notation may define one specific integer for the corresponding variable, such as a specific n* for the variable n, a specific m* for the variable m, etc.

In this exemplary configuration, each memory cell 102 may be a (K+2)-terminal memory cell having K plateline terminals 104, a first bitline terminal 106, and a second bitline terminal 108. The plateline terminal 104(k=k*) of a respective memory element 301(k*, m*, n*) may be coupled to the corresponding plateline PL(k*, m*, n*). The first bitline terminal 106 of the group of memory cells 301(k=1 to K, m*, n*) may be coupled to the corresponding bitline BL(n*). The second bitline terminal 108 of the group of memory cells 301(k=1 to K, m*, n*) may be coupled to the corresponding wordline WL(m*).

The memory device may include a controller 600 (also referred as to control device), e.g., including control circuitry 422 and/or the operation control circuitry 560 (see FIG. 3A). The controller 600 may be configured to apply a respective voltage to each control line described herein. The controller 600 may be configured to apply and/or modify the plate voltage, V_{PL}, (via the corresponding plateline PL(k*, m*, n*)) at the plateline terminal 104, a bitline voltage, V_{BL}, (via the corresponding bitline BL(n*)) at the first bitline terminal 106, and a wordline voltage, V_{WL}, (via the corresponding wordline WL(m*)) at the second bitline terminal 108 of the memory cells in order to access the memory element 301(k*, m*, n*). The controller 600 may be configured to initiate a write operation to write a memory state to the accessed memory element 301(k* m*, n*). The controller 600 may be configured to initiate a read operation to read the memory state of the accessed memory element 301(k* m*, n*).

“Writing” to a memory cell, as used herein, may be understood as bringing the memory cell into one of at least two different memory states. Writing a memory cell may also be referred to as programming the memory cell, wherein the memory state the memory cell is residing in after programming may be called “programmed state”. Therefore, the memory cell may also be referred to as state-programmable memory cell.

“Reading” a memory cell (e.g., reading from a memory cell), as used herein, may be understood as determining the memory state the memory cell is residing in (e.g., programmed to). In general, a memory cell may be read either non-destructively (if the read-out operation does not change the memory state the memory cell is residing in) or destructively (if the read-out operation changes the memory state the memory cell is residing in). Thus, a destructive read-out operation may require a write operation subsequent to read-out in order to program again the memory state of the memory cell.

In the following, various working examples are provided that may include one or more aspects described herein (e.g., with reference to a multilevel state-programable memory element). It may be intended that aspects described in relation to the circuits and components thereof may apply also to the described method(s), and vice versa.

A working example 1 increases the reliability of accessing one or more memory cells, e.g., for reading and/or writing operations. By controlling the plate voltage of unselected memory elements within a selected access group, the risk of parasitic change of the memory state of the unselected memory elements is reduced. The protection voltage helps preventing a disturbance to the unselected memory elements during access of one or more selected memory elements, thereby increasing reliability of the memory device.

A working example 2 (e.g., in accordance with working example 21) reduces the footprint of the memory device by using stacked memory elements as access group. This reduces the footprint of the memory device.

A working example 3 (e.g., in accordance with one of working examples 1 to 32) enhances the reliability further by changing the protection voltage in a writing operation.

A working example 4 (e.g., in accordance with one of working examples 1 to 43) enhances the reliability further by changing the protection voltage, when a level of one or more operation voltages are changed.

A working example 5 (e.g., in accordance with one of working examples 1 to 54) enhances the reliability further by changing the protection voltage by an operation voltage swing, when the access circuitry is in an write operation mode.

A working example 6 (e.g., in accordance with one of working examples 1 to 65) enhances the reliability further by changing the protection voltage by an operation voltage swing, when the operation mode of the access circuitry is changed, e.g., from sensing mode to re-writing mode or from a first writing mode to a second writing mode.

A working example 7 (e.g., in accordance with one of working examples 1 to 76) reduces the footprint of the memory device by providing multiple groups of (e.g., stacked) memory elements and, for each of the groups an access switch, by which the group is addressable. Each group of (e.g., stacked) memory elements may include 2 or more memory elements, e.g., 3 or more memory element, e.g., 4 or more memory elements.

In the following, various examples are provided that may include one or more aspects described above, e.g., with reference to a multilevel state-programable memory element. It may be intended that aspects described in relation to the circuits and components thereof may apply also to the described method(s), and vice versa.

Example 1 (e.g., a cell operation circuit for operating a set of memory elements) is configured according to one of the accompanying claims and/or includes: an access circuitry configured, e.g., in an access operation mode (e.g., a write operation mode or a read operation mode), to access (e.g., read from or write to) a first memory element of the set; a control circuitry configured to provide a protection voltage, to which a second memory element of the set is exposed.

Example 2 is configured according to example 21, wherein the control circuitry is configured to provide the protection voltage, to which the second memory element of the set is exposed, when the access circuitry is configured (e.g., operated) to access the first memory element of the set.

Example 3 is configured according to one of examples 1 to 32, wherein to access the first memory element includes, e.g., when the access circuitry is configured (e.g., operated) to access the first memory element, the access circuitry being configured to provide a stimulation voltage (e.g., via a first plate line and/or as plate line voltage), to which the first memory element is exposed.

Example 4 is configured according to one of examples 1 to 43, wherein the access circuitry (also referred as to memory access circuitry) includes an access node (also referred as to memory access node), at which an access voltage (e.g., the switching voltage and/or as output signal) is developed, e.g., to which the first memory element and/or the second memory element are exposed, e.g., via a bit line coupled to the access node.

Example 5 is configured according to one of examples 1 to 54, wherein the access circuitry is configured (e.g., operated) to access (e.g., write to or read from) the first memory element based on the access voltage, e.g., developed at the access node of the access circuitry.

Example 6 is configured according to one of examples 1 to 65, wherein the access voltage is developed at the access node based on a switching change of the first memory element.

Example 7 is configured according to one of examples 1 to 76, wherein the access circuitry is configured, e.g., in the read operation mode, to provide a read voltage (e.g., to a first terminal thereof), to which the first memory element is exposed to deliver the switching charge.

Example 8 is configured according to one of examples 1 to 87, wherein the control circuitry is configured to provide the protection voltage, to which the second memory element of the set is exposed, when the second memory element is exposed to an access voltage (e.g., based on voltage response of the first memory element), e.g., to which the first memory element and/or the access circuitry are exposed.

Example 9 is configured according to one of examples 1 to 98, wherein the access circuitry comprises an access node, at which the access voltage is developed.

Example 10 is configured according to one of examples 1 to 109, wherein the access circuitry includes a first input terminal (e.g., to receive a first operation voltage) and a second input terminal (e.g., to receive a second operation voltage, e.g., less than the first operation voltage), e.g., when the access circuitry is configured (e.g., operated) to access the first memory element.

Example 11 is configured according to one of examples 1 to 1110, wherein the access circuitry is configured to receive a first operation voltage at the first input terminal and to receive a second operation voltage (e.g., less than the first operation voltage) at second input terminal to access a first memory element of the set.

Example 12 is configured according to one of examples 1 to 1211, wherein the protection voltage is between the first operation voltage and the second operation voltage.

Example 13 is configured according to one of examples 1 to 1312, wherein the access circuitry is configured (e.g., operated) to access (e.g., read from or write to) the first memory element of the set based on an access voltage at an access node of the access circuitry.

Example 14 is configured according to one of examples 1 to 1413, wherein the access voltage (e.g., in the read operation mode) is developed to one of a first voltage level (e.g., of the first operation voltage) associated with a first memory state (e.g., representing a first logic state) of the first memory element or a second voltage level (e.g., of the second operation voltage) associated with a second memory state (e.g., representing a second logic state) of the first memory element.

Example 15 is configured according to one of examples 1 to 1514, wherein the protection voltage is between the first voltage level and the second voltage level.

Example 16 is configured according to one of examples 1 to 1615, wherein the access circuitry is configured (e.g., operated) to access a (e.g., multi-bit memory) cell including the first memory element and the second memory element, e.g., via the same access switch.

Example 17 is configured according to one of examples 1 to 1716, wherein the access circuitry is configured to access the first memory element and the second memory element via the same access switch and/or the same bit line.

Example 18 is configured according to one of examples 1 to 1817, wherein the access circuitry configured, in an access operation mode, to access the first memory element of the set and includes the first input terminal to receive, in the access operation mode, the first operation voltage and a second input terminal to receive, in the access operation mode, the second operation voltage (e.g., less than the first operation voltage).

Example 19 is configured according to one of examples 1 to 1918, wherein the protection voltage is, in a first phase of the access operation mode, at a first protection voltage level and, in a second phase of the access operation mode, at a second protection voltage level different from the first protection voltage level, e.g., by an operation voltage swing.

Example 20 is configured according to one of examples 1 to 2019, wherein the first operation voltage and/or the second operation voltage are, in a first phase of the access operation mode, at a first operation voltage level and, in a second phase of the access operation mode, at a second operation voltage level different from the first operation voltage, e.g., by an operation voltage swing.

Example 21 is configured according to one of examples 1 to 2120, wherein the access operation mode provides a read operation for reading from the first memory element.

Example 22 is configured according to one of examples 1 to 2221, wherein the access operation mode provides a write operation for writing to the first memory element.

Example 23 is configured according to one of examples 1 to 2322, wherein the write operation is based on a (e.g., a access voltage as) result of the read operation (also referred as to re-write operation) or based on a data signal, e.g., representing a logical state (e.g., to be programmed to the first memory element).

Example 24 is configured according to one of examples 1 to 2423, wherein the access operation mode provides, e.g., as write operation, a re-writing operation based on a (e.g., a access voltage as) result of the read operation.

Example 25 is configured according to one of examples 1 to 2524, wherein the access circuitry is configured to, in a read operation mode (e.g., as access operation mode), to read from or, in a write operation mode (e.g., as access operation mode), write to a first memory element of the set (e.g., based on an access voltage at the access node).

Example 26 is configured according to one of examples 1 to 2625, wherein the protection voltage is, in the read operation mode, at a first protection voltage level and, in the write operation mode, at a second protection voltage level different from the first protection voltage level, e.g., by an operation voltage swing.

Example is configured according to one of examples 1 to 2625, wherein the control circuitry is configured to change (e.g., increase) the protection voltage, e.g., when the first or second operation voltages change (e.g., increase).

Example 27 is configured according to one of examples 1 to 2726, wherein the control circuitry is configured to determine, whether a voltage level of the first or second operation voltages changes, and based thereon provide the protection voltage, e.g., change (e.g., increase) the protection voltage.

Example 28 is configured according to one of examples 1 to 2827, wherein the control circuitry is configured to determine, whether the access circuitry is in a first type of the access (e.g., write) operation mode or in a second type of the access (e.g., write) operation mode, and based thereon provide the protection level. The first and second types may differ from each other, by the type of memory state (e.g., “0” or “1”) to be programmed to the first memory element.

Example 29 is configured according to one of examples 1 to 2928, wherein the control circuitry is configured to determine the first memory element as selected memory element and the second memory element as unselected memory element, e.g., and based thereon provide the protection voltage, to which the second memory element is exposed.

Example 30 is configured according to one of examples 1 to 3029, wherein the protection voltage is provided based on (e.g., as function of) one of the first operation voltage level or the second operation voltage, e.g., by a (e.g., plateline) voltage control circuitry (e.g., implemented by the control circuitry).

Example 31 is configured according to one of examples 1 to 3130, wherein the protection voltage is provided via a second plateline associated with (e.g., coupled to) the second memory element.

Example 32 is configured according to one of examples 1 to 3231, wherein the first memory element is accessed via a bitline associated (e.g., coupled to) the first memory element.

Example 33 is configured according to one of examples 1 to 3332, wherein the first memory element is accessed via a access terminal associated (e.g., coupled to) each of the first and second memory elements.

Example 34 is configured according to one of examples 1 to 3433, wherein the first memory element is accessed via an access switch terminal associated (e.g., coupled to) each of the first and second memory elements.

Example 35 is configured according to one of examples 1 to 3534, wherein the control circuitry is configured to change the protection voltage based on whether the access circuitry is in a read operation mode or in a write operation mode.

Example 36 is configured according to one of examples 1 to 3635, wherein the control circuitry is configured to provide a wordline voltage to an access switch, when the access circuitry is configured (e.g., operated) to access the first memory element via the access switch.

Example 37 is configured according to one of examples 1 to 3736, wherein the control circuitry is configured provide an wordline voltage to the access switch, when the access circuitry is configured (e.g., operated) to access the second memory element via the access switch.

Example 38 is configured according to one of examples 1 to 3837, wherein the control circuitry is configured to determine the first memory element as selected memory element (also referred as to active memory element or to addressed memory element) and the second memory element as unselected memory element (also referred as to inactive memory element).

Example 39 is configured according to one of examples 1 to 3938, wherein the control circuitry is configured to determine, whether the access circuitry is in a read operation mode or in a write operation mode, and based thereon provide the protection level.

Example 40 is configured according to one of examples 1 to 4039, wherein to access the first memory element comprises one of: to read from the first memory element, e.g., in the read operation mode, and to write to the first memory element, e.g., in the write operation mode.

Example 41 is configured according to one of examples 1 to 4140, wherein protection voltage is provided, when the first memory element is accessed.

Example 42 is configured according to one of examples 1 to 4241, wherein the control circuitry is configured to provide a stimulation voltage (e.g., plate line voltage and/or via a plate line), to which the first memory element is exposed, when the access circuitry is configured to access the first memory element.

Example 43 is configured according to one of examples 1 to 4342, wherein the stimulation voltage is configured to change a memory state of the first memory element.

Example 44 is configured according to one of examples 1 to 4443, wherein the stimulation voltage is a read voltage or a writing voltage (e.g., programming voltage) of the first memory element.

Example 45 is configured according to one of examples 1 to 4544, wherein the protection voltage differs more from the stimulation voltage than from the first operation voltage and/or the second operation voltage.

Example 46 is configured according to one of examples 1 to 4645, further comprising a first plateline (e.g., coupled to the first memory element), via which the first memory element is exposed to a writing voltage.

Example 47 is configured according to one of examples 1 to 4746, further comprising a second plateline (e.g., coupled to the second memory element), via which the second memory element is exposed to the protection voltage.

Example 48 is configured according to one of examples 1 to 4847, wherein the first plateline and the second plateline are disposed over each other, and preferably further over a substrate.

Example 49 is configured according to one of examples 1 to 4948, wherein the control circuitry is configured to increase a (e.g., plate line) voltage, to which the first memory element is exposed, by at least a programming voltage of the memory element, e.g., from a lower operation voltage.

Example 50 is configured according to one of examples 1 to 5049, wherein the first plateline is configured to be coupled to a further first memory element complementary to the first memory element.

Example 51 is configured according to one of examples 1 to 5150, wherein the second plateline is configured to be coupled to a further second memory element complementary to the second memory element.

Example 52 is configured according to one of examples 1 to 5251, wherein the plate line voltage is, in the read operation mode, a first plate line voltage level and, in the write operation mode, at a second plate line voltage level different from the first plate line voltage level, e.g., by an operation voltage swing.

Example 53 is configured according to one of examples 1 to 5352, further comprising an access switch, which couples the access circuitry with a first terminal, which is configured to couple (e.g., ohmic) the first memory element with the second memory, e.g., a common access terminal.

Example 54 is configured according to one of examples 1 to 5453, wherein the access voltage (also referred as to memory access voltage) is indicative of the memory state programmed to the first memory element or to be programmed to the first memory element.

Example 55 is configured according to one of examples 1 to 5554, wherein the second memory element is exposed to the access voltage.

Example 56 is configured according to one of examples 1 to 5655, wherein the protection voltage is, in the read operation mode, at a first level and, in the write operation mode, at a second level different from the first level.

Example 57 is configured according to one of examples 1 to 5756, wherein the first level of the protection voltage is less than the second level of the protection voltage.

Example 58 is configured according to one of examples 1 to 5857, wherein the protection voltage is between the first voltage level associated with a first memory state and the second voltage level associated with a second memory state e.g., differing from an average of the first voltage level and the second voltage level less than from the first voltage level and from the second voltage level.

Example 59 is configured according to one of examples 1 to 5958, wherein the protection voltage is between the first operation voltage and the second operation voltage, e.g., differing from an average of the first operation voltage and the second operation voltage less than from the first operation voltage and/or from the second operation voltage.

Example 60 is configured according to one of examples 1 to 6059, wherein the protection voltage differs from the first operation voltage and/or from the second operation voltage by a maximum of ½ (or less, e.g., ⅓) of the programming voltage of the first and/or second memory elements.

Example 61 is configured according to one of examples 1 to 6160, wherein the protection voltage differs from the first voltage level associated with a first memory state and/or from the second voltage level associated with a second memory state by minimum of ½ (e.g., ⅓) of the programming voltage of the second memory element of more.

Example 62 is configured according to one of examples 1 to 6261, wherein the access circuitry comprises one or more access switches, of which each access switch separates two group of memory elements (e.g., providing a memory cell) of the set from each other.

Example 63 (e.g., a memory device) includes: the cell operation circuit of one of examples 1 to 6362, and the set of memory elements, which are preferably stacked and/or coupled to each other, e.g., ohmic (e.g., monolithically) and/or by a common bitline.

Example 64 (e.g., the memory device) is configured according to one of examples 1 to 6463, wherein the cell operation circuit comprises multiple access switches and wherein the set of memory elements comprises multiple groups of memory elements, of which a first group of memory elements comprises the first memory element and the second memory element, wherein the multiple groups comprise one group of memory cells per access switch, which is coupled to each of the memory elements of the group.

Example 65 is configured in accordance with one of examples 1 to 6564, wherein the access circuitry includes a sense amplifier.

Example 66 is configured in accordance with one of examples 1 to 6665, wherein the access voltage is developed at the access node (e.g., via a wordline) based on a switching voltage indicative of the programmed state of the memory element.

Example 67 is configured in accordance with one of examples 1 to 6766, wherein to read from the memory element comprises to determine a programmed state of the memory element based on an access voltage, which is developed at the access node (e.g., via a wordline) based on a switching voltage indicative of the programmed state of the memory element.

Example 68 is configured in accordance with one of examples 1 to 6867, the control circuitry further configured to control (e.g., via an access switch) a coupling of the access node to the first and second memory elements (e.g., via a wordline).

Example 69 is configured in accordance with one of examples 1 to 6968, wherein each switch is provided by one or more transistors.

Example 70 is configured in accordance with one of examples 1 to 7069, wherein the first memory element comprises a second terminal (e.g., plateline terminal) to receive a programming voltage, e.g., a read voltage (e.g., plate voltage).

Example 71 is configured in accordance with one of examples 1 to 7170, wherein a difference between the first operation voltage and the second operation voltage is more than about 1 Volt (e.g., about 3 Volt) and/or less than about 20 Volt, e.g., 10 Volt.

Example 72 is configured according to one of one of examples 1 to 7271, wherein the first and/or second memory elements includes a ferroelectric capacitor, wherein the programmed state includes preferably a remanent polarization state of the ferroelectric capacitor.

Example 73 is configured according to one of one of examples 1 to 7372, wherein the access node includes or adjoins a bitline (e.g., BLE), e.g., configured to access the first and/or second memory elements.

Example 74 is configured according to one of one of examples 1 to 7473, wherein the access circuitry includes a reference access node, which includes or adjoins a further bitline (e.g., BLO), for example, the further bitline configured to access a complementary first memory element and/or a complementary second memory element of the set.

Example 75 is configured according to one of one of examples 1 to 7574, wherein the first and/or second memory elements provide multiple remanent states as programmed states.

Example 76 is configured according to one of one of examples 1 to 7675, wherein the access (e.g., sensing) circuitry is configured to sense a voltage level at the access node (in this context also referred as to sensing node) and/or convert (e.g., amplify) the voltage level at the sensing node into an output signal indicative of the programmed state of the memory element.

Example 77 is configured according to one of one of examples 1 to 7776, wherein the access node include an electric conductor (e.g., being metallic), e.g., providing an electrically conductive line.

Example 78 is configured according to one of one of examples 1 to 7877, wherein the first operation voltage (e.g., Vpwr) is a “high” operation voltage and the second operation voltage (e.g., Vpwl) is a “low” operation voltage.

Example 79 is configured according to one of one of examples 1 to 7978, wherein the access circuitry implements, e.g., during the read operation, a sense circuitry, e.g., including a sensing amplifier; wherein, preferably, the sense circuitry is configured to provide an output signal indicative of the programmed state of the first memory element based on the access voltage, e.g., being based on the state indicative voltage swing.

Example 80 is configured according to one of one of examples 1 to 8079, wherein access circuitry implements, e.g., during the write operation, a write circuitry, e.g., including the sensing amplifier; wherein, preferably, the write circuitry is configured to provide a data signal indicative of the state to be programmed to the first memory element based on the access voltage, e.g., being based on the data signal.

Example 81 is configure Example 82 is configured according to one of one of examples 1 to 8281, wherein the first operation voltage is supplied to the access circuitry and/or to the second memory element.

Example 83 is configured according to one of one of examples 1 to 8382, wherein the second operation voltage is supplied to the access circuitry and/or to the control circuitry.

Example 84 is configured according to one of one of examples 1 to 8483, wherein a latch of the access circuitry is coupled between the first input terminal and the second input terminal.

Example 85 is configured according to one of one of examples 1 to 8584, wherein the second operation voltage differs more from the first operation voltage than from the protection voltage.

Example 86 is configured according to one of one of examples 1 to 8685, wherein the second operation voltage differs from electrical ground less than the protection voltage.

Example 87 is configured according to one of one of examples 1 to 8786, wherein the first memory element is delivering the voltage swing and/or exposed to the programming voltage, when the sensing node is at ground.

Example 88 is configured according to one of one of examples 1 to 8887, wherein the protection voltage is more than the second operation voltage (e.g., GND), e.g., by a minimum of 0.1 Volts, e.g., by a minimum of 0.2 Volts, e.g., by a minimum of 0.3 Volts.

Example 89 is configured according to one of one of examples 1 to 8988, wherein the protection voltage is more than the second operation voltage (e.g., GND), e.g., by a maximum of 5 Volts, e.g., by a maximum of 2 Volts, e.g., by a maximum of 1 Volts, e.g., by a maximum of 0.5 Volt.

Example 90 is configured according to one of one of examples 1 to 9089, wherein the control circuitry is configured to increase a voltage level, to which the first memory element is exposed, to initiate that a sensing voltage is developed as access voltage at the access node.

Example 91 is configured according to one of one of examples 1 to 9190, wherein the sensing voltage is developed (e.g., at a sensing node) in response to the memory element being exposed to the programming voltage and/or when the voltage, to which the memory element is exposed, is increased by the programming voltage.

Example 92 is configured according to one of one of examples 1 to 9291, wherein a voltage level of the wordline is increased after the access node is (e.g., galvanically) separated from the first reference voltage.

Example 93 is configured according to one of one of examples 1 to 9392, wherein first memory element and the second memory element are stacked over each other.

Example 94 is configured according to one of one of examples 1 to 9493, wherein first memory element and the second memory element are provided by a (e.g., columnar and/or monolithic) polarizable material.

Example 95 is configured according to one of one of examples 1 to 9594, wherein first memory element and the second memory element are provided in accordance with a 3D memory architecture.

Example 96 is configured according to one of one of examples 1 to 9695, wherein the control circuitry is configured to address the first memory element and the second memory by a common wordline signal, e.g., provided to a common access switch.

Example 97 is configured according to one of one of examples 1 to 9796, wherein the control circuitry is configured to address the first memory element and the second memory by a common access switch.

Example 98 is configured according to one of one of examples 1 to 9897, further comprising an access switch coupled to the first memory element and the second memory element.

Example 99 is configured according to one of one of examples 1 to 9998, wherein the second memory element is coupled to the access switch via the first memory element.

Example 100 is configured according to one of one of examples 1 to 10099, further comprising multiple groups of (e.g., stacked) memory element, of which a first group includes the first memory element and the second memory element.

Example 101 is configured according to one of one of examples 1 to 101100, further comprising multiple groups of (e.g., stacked) memory elements and, for each of the groups an access switch, by which the group is addressable (e.g., accessible) by the access circuitry.

Example 102 is configured according to one of one of examples 1 to 102101, further comprising a first plateline leading (e.g., coupled to) to the first memory element and a second plateline leading (e.g., coupled to) to the second memory element, wherein the first plateline and the second plateline are disposed over each other and/or are coupled with each other by a polarizable material (e.g., a monolithic block thereof), which provides the first memory element and the second memory element.

Example 103 is configured according to one of one of examples 1 to 103102, wherein the first memory element and/or the second memory element are provided as state-programmable memory element (e.g., a ferroelectric memory element, e.g., providing a ferroelectric capacitor).

Example 104 is configured according to one of one of examples 1 to 104103, further including, for each of the first memory element and the second memory element, a plateline terminal (e.g., configured to be coupled to a plateline).

Example 105 is configured according to one of one of examples 1 to 105104, further including a access terminal coupled to the first memory element, wherein the second memory element is coupled to the access terminal via the first memory element.

Example 106 is configured according to one of one of examples 1 to 106105, a memory cell including the first memory element and the second memory element, wherein the memory cell includes less access terminals (e.g., configured to be coupled to a bitline) than plateline terminals.

Example 107 is configured according to one of one of examples 1 to 107106, a memory cell including the first memory element and the second memory element, wherein the memory cell includes less wordline terminals (e.g., configured to be coupled to a wordline) than plateline terminals.

Example 108 is configured according to one of one of examples 1 to 108107, wherein the control circuitry is configured to provide a protection voltage, to which the second memory element is exposed, when the first memory element is accessed (e.g., written or read).

The terms “at least one” and “one or more” may be understood to include any integer number greater than or equal to one, i.e. one, two, three, four, [ . . . ], etc. is the term “a plurality” or “a multiplicity” may be understood to include any integer number greater than or equal to two, i.e. two, three, four, five, [ . . . ], etc. is the phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device.

Each voltage, as detailed herein, may be, in analogy, expressed as voltage level, e.g., relative to a reference voltage, e.g., the lower operation voltage. The references made herein may apply to voltages and voltage levels in analogy.

While the invention has been particularly shown and described with reference to specific aspects, it should be understood by those skilled in the art that various changes in form and detail may be made therein without departing from the spirit and scope of the invention as defined by the appended examples. The scope of the invention is thus indicated by the appended examples and all changes, which come within the meaning and range of equivalency of the examples, are therefore intended to be embraced.

What is claimed is:

1. A cell operation circuit for operating a set of memory elements, the cell operation circuit comprising:
an access circuitry comprising a first input terminal and a second input terminal and being configured to receive a first operation voltage at the first input terminal and to receive a second operation voltage at a second input terminal to access a first memory element of the set;
a control circuitry configured to provide a protection voltage, to which a second memory element of the set is exposed, when the first memory element is accessed by the access circuitry, wherein the protection voltage is between the first operation voltage and the second operation voltage.

2. The cell operation circuit of claim 21, wherein the control circuitry is configured to provide the protection voltage, to which the second memory element of the set is exposed, when the second memory element is further exposed to an access voltage, to which the first memory element is exposed.

3. The cell operation circuit of claim 32, wherein the access circuitry comprises an access node, at which the access voltage is developed based on a switching charge delivered by the first memory element.

4. The cell operation circuit of claim 43, wherein the access voltage is developed to one of a voltage level of the first operation voltage associated with a first memory state of the first memory element or a voltage level of the second operation voltage associated with a second memory state of the first memory element.

5. The cell operation circuit of claim 1, wherein the control circuitry is configured to increase the protection voltage, when one of the first operation voltage or the second operation voltages increase.

6. The cell operation circuit of claim 1, wherein the control circuitry is configured to determine when a level of the first or second operation voltages changes and, based thereon, provide the protection voltage.

7. The cell operation circuit of claim 1, further comprising a bitline, wherein the access circuitry is configured to access the first memory element and the second memory element via the bitline.

8. The cell operation circuit of claim 1, wherein the control circuitry is configured to determine the first memory element as a selected memory element and the second memory element as an unselected memory element.

9. The cell operation circuit of claim 1, wherein the control circuitry is configured to provide a wordline voltage to an access switch when the first memory element is accessed by the access circuitry via the access switch, and wherein the control circuitry is configured to provide the wordline voltage to the access switch when the second memory element is accessed by the access circuitry via the access switch.

10. The cell operation circuit of claim 1, wherein the control circuitry is configured to change the protection voltage based on whether the access circuitry is in a read operation mode or in a write operation mode.

11. The cell operation circuit of claim 1, wherein to access the first memory element comprises one of: to read from the first memory element or to write to the first memory element.

12. The cell operation circuit of claim 1, wherein the protection voltage differs from the first operation voltage, the second operation voltage by one third of a programming voltage of the first memory element, or both.

13. The cell operation circuit of claim 1312, further comprising a first plateline, wherein to access the first memory element includes to provide the programming voltage, to which the first memory element is exposed via the first plateline.

14. The cell operation circuit of claim 1413, further comprising a second plateline via which the second memory element is exposed to the protection voltage, wherein the first plateline and the second plateline are disposed over each other.

15. The cell operation circuit of claim 1, wherein the protection voltage differs more from the first operation voltage than from an average of the first operation voltage and the second operation voltage.

16. The cell operation circuit of claim 1, wherein the first memory element and the second memory element are monolithically coupled to each other.

17. The cell operation circuit of claim 1, wherein the first memory element and the second memory element are stacked over each other.

18. The cell operation circuit of claim 1, wherein the first memory element includes a ferroelectric capacitor.

19. A cell operation circuit for operating a set of memory elements, the cell operation circuit comprising:
an access circuitry comprising an access node, wherein the access circuitry is configured to access a first memory element of the set based on an access voltage at the access node, wherein the access voltage is at one of a first voltage level associated with a first memory state of the first memory element or a second voltage level associated with a second memory state of the first memory element;
a control circuitry configured to provide a protection voltage, to which a second memory element of the set is exposed, when the access circuitry is configured to access a first memory element of the set, wherein the protection voltage is between the first voltage level and the second voltage level.

20. A cell operation circuit for operating a set of memory elements, the cell operation circuit comprising:
an access circuitry comprising an access node, wherein the access circuitry is configured to, in an access operation mode, access a first memory element of the set based on an access voltage at the access node;
a control circuitry configured provide a protection voltage, to which a second memory element of the set is exposed, wherein the protection voltage is, in a first phase of the access operation mode, at a first level and, in a second phase of the access operation mode, at a second level different from the first level.
